(19) United States
(12) Patent Application Publication
(10) Pub. No.: US 2013/0160842 A1
(43) Pub. Date: Jun. 27, 2013

(54) DYE SENSITIZED SOLAR CELL

(71) Applicant: MKE TECHNOLOGY CO., LTD, Taipei City (TW)

(72) Inventors: Kuang-Feng CHUNG, Taipei City (TW); Chien-Tung TENG, Taipei City (TW); Wei-Lun HSU, Taipei City (TW)

(73) Assignee: MKE TECHNOLOGY CO., LTD, Taipei City (TW)

(21) Appl. No.: 13/658,521

(22) Filed: Oct. 23, 2012

(30) Foreign Application Priority Data
Dec. 27, 2011 (TW) 100148801

(51) Int. Cl. H01L 31/0224

(52) U.S. Cl. 136/256

(57) ABSTRACT

A dye sensitized solar cell comprises a transparent conducting substrate, a dye layer, an electricity-collecting electrode, an insulating adhesive, and a metal foil. The transparent conducting substrate has a transparent substrate and a transparent conducting layer that is disposed on the transparent substrate. The dye layer is disposed on the transparent conducting layer. The electricity-collecting electrode is disposed on the transparent conducting layer and around the dye layer. The insulating adhesive is disposed around the dye layer and on the electricity-collecting electrode. The metal foil is disposed on the dye layer and the insulating adhesive.

### CROSS REFERENCE TO RELATED APPLICATIONS

This Non-provisional application claims priority under 35 U.S.C. §119(a) on Patent Application No(s). 100148801 filed in Taiwan, Republic of China on Dec. 27, 2011, the entire contents of which are hereby incorporated by reference.

### BACKGROUND OF THE INVENTION

1. Field of Invention

The invention relates to a solar cell and, in particular, to a dye sensitized solar cell.

2. Related Art

Solar energy will not cause environmental pollution, and can be easily acquired and never exhausted, becoming an important resource of alternative energy. The solar cell utilizing solar energy is a kind of photoelectric converting device, which can receive solar light and converts solar energy to electric energy.

The solar cell has many types, such as silicon-based solar cell, compound semiconductor solar cell, organic solar cell, or dye sensitized solar cell (DSSC). As to the DSSC, it includes two conducting substrates attached to each other. One of the conducting substrate has titanium dioxide (TiO2) thereon, which absorbs the dye and thus becomes a dye layer, and the other one has a catalytic layer, such as platinum (Pt). However, since the conventional DSSC is composed of two substrates, the size and the thickness of the product is increased, causing disadvantage to compactness.

Therefore, it is an important subject to provide a dye sensitized solar cell that has a new structure to advantage the compactness of the product for improving the product's competitiveness.

### SUMMARY OF THE INVENTION

In view of the foregoing subject, an objective of the invention is to provide a dye sensitized solar cell that has a new structure to advantage the product's compactness as well as competitiveness.

To achieve the above objective, a dye sensitized solar cell of the invention comprises a transparent conducting substrate, a dye layer, an electricity-collecting electrode, an insulating adhesive, and a metal foil. The transparent conducting substrate has a transparent substrate and a transparent conducting layer that is disposed on the transparent substrate. The dye layer is disposed on the transparent conducting layer. The electricity-collecting electrode is disposed on the transparent conducting layer and around the dye layer. The insulating adhesive is disposed around the dye layer and on the electricity-collecting electrode. The metal foil is disposed on the dye layer and the insulating adhesive.

In one embodiment, the transparent conducting layer is a continuous transparent conducting layer or includes a plurality of unconnected transparent conducting portions.

In one embodiment, the transparent conducting layer includes a plurality of unconnected transparent conducting portions, and the dye layer includes a plurality of unconnected dye portions that are respectively disposed on the transparent conducting portions.

In one embodiment, the dye layer includes a plurality of unconnected dye portions, each of which is a regular polygon or a rectangle.

In one embodiment, the electricity-collecting electrode includes at least one frame portion.

In one embodiment, a side of the frame portion has a conducting connection portion.

In one embodiment, the conducting connection portions are disposed at a side or opposite sides of the transparent conducting substrate.

In one embodiment, the metal foil is a continuous metal foil or includes a plurality of unconnected metal portions.

In one embodiment, the material of the metal foil includes titanium, nickel, or stainless steel.

In one embodiment, the dye sensitized solar cell further comprises a package adhesive that is disposed on the metal foil.

In one embodiment, the package adhesive includes at least one first conducting hole and at least one second conducting hole.

In one embodiment, the first conducting hole is electrically connected with the electricity-collecting electrode, and the second conducting hole is electrically connected with the metal foil.

In one embodiment, the dye sensitized solar cell further comprises a double-surface circuit board having a first surface and a second surface opposite to the first surface. The first surface has at least one first conducting pad and at least one second conducting pad, the first conducting pad is electrically connected with the first conducting hole, and the second conducting pad is electrically connected with the second conducting hole.

In one embodiment, the double-surface circuit board further has two holes, the second surface of the double-surface circuit board has a third conducting pad and a fourth conducting pad, one of the holes is connected with the third conducting pad and one of the first conducting pads, and the other hole is connected with the fourth conducting pad and one of the second conducting pads.

In one embodiment, the double-surface circuit board further has a transferring pad that is disposed on the second surface and at an edge of the double-surface circuit board and electrically connected with the fourth conducting pad.

As mentioned above, the DSSC of the invention only has a substrate, on which the dye layer, the electricity-collecting electrode, the insulating adhesive, and the metal foil are disposed. Besides, the metal foil and the electricity-collecting electrode can be included in an electrical loop. Furthermore, the insulating adhesive insulates the metal foil and the electricity-collecting electrode (with the dye layer) from each other so that the DSSC can function normally to conduct a photoelectric conversion. Accordingly, the DSSC of the invention has a new structure to advantage the product's compactness as well as the product competitiveness.

### BRIEF DESCRIPTION OF THE DRAWINGS

The invention will become more fully understood from the detailed description and accompanying drawings, which are given for illustration only, and thus are not limitative of the present invention, and wherein:

FIGS. 1A to 1D are schematic diagrams of a dye sensitized solar cell of a first embodiment of the invention;

FIGS. 2A and 2B are schematic diagrams of a double-surface circuit board of the dye sensitized solar cell of the first embodiment of the invention;

FIGS. 3A to 3D are schematic diagrams of a dye sensitized solar cell of a second embodiment of the invention;

FIG. 4 is a schematic view of the frame portion of the electricity-collecting electrode and the dye portion of the dye layer, both with a geometric figure of regular hexagon, of the dye sensitized solar cell of second embodiment of the invention;

FIGS. 5A and 5B are schematic diagrams of another dye sensitized solar cell of the second embodiment of the invention, in which the conducting connection portions are disposed at the opposite sides of the transparent conducting substrate;

FIGS. 6A and 6B are schematic diagrams of a double-surface circuit board of the dye sensitized solar cell of the second embodiment of the invention;

FIG. 7 is a schematic diagram of an equilateral hexagon inscribed in a circle;

FIGS. 8A and 8B are schematic diagrams showing that the titanium dioxide of the dye-absorbing layer is disposed on the transparent conducting substrate; and

FIGS. 9A and 9B are schematic diagrams showing the dye portions in the three different forms and the electron transport routes of the electricity-collecting electrode.

### DETAILED DESCRIPTION OF THE INVENTION

The present invention will be apparent from the following detailed description, which proceeds with reference to the accompanying drawings, wherein the same references relate to the same elements.

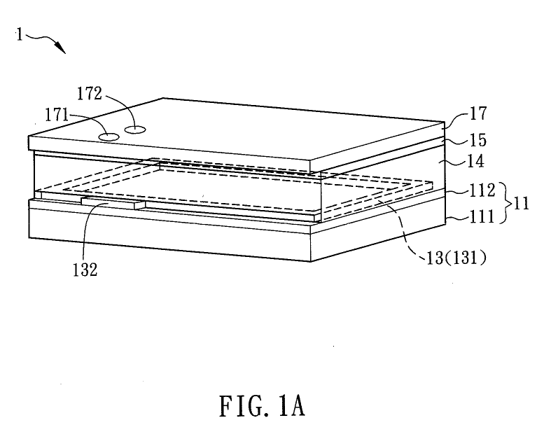

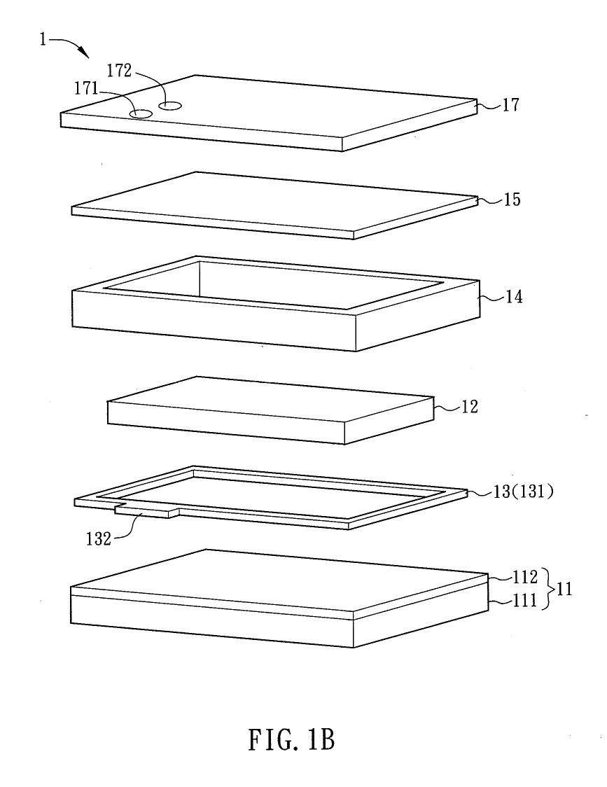

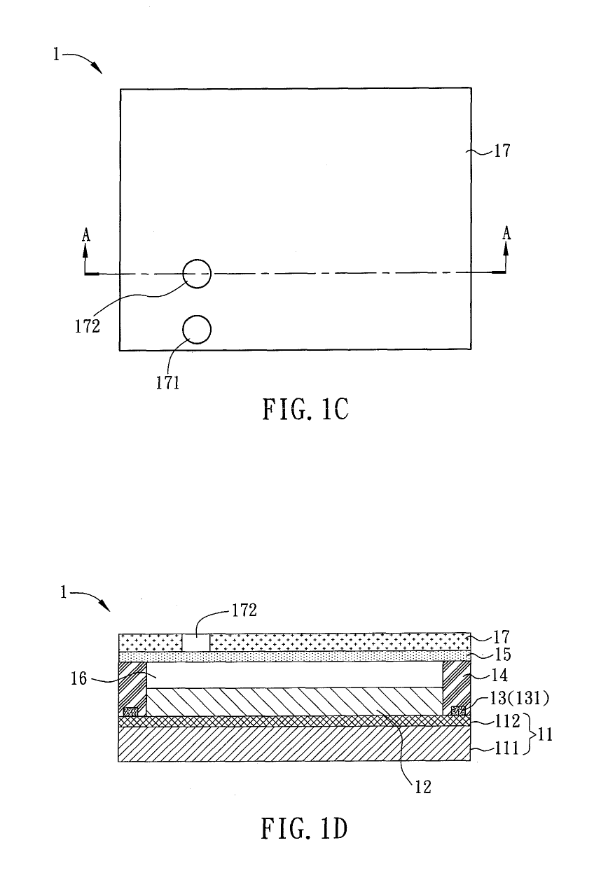

FIG. 1A is a schematic diagram of a dye sensitized solar cell (DSSC) 1 of a first embodiment of the invention, FIG. 1B is an exploded diagram of the DSSC 1, FIG. 1C is a top view of the DSSC 1, and FIG. 1D is a sectional diagram of the DSSC 1 taken along the line A-A in FIG. 1C. Referring to FIGS. 1A and 1D, the DSSC 1 includes a transparent conducting substrate 11, a dye layer 12, an electricity-collecting electrode 13, an insulating adhesive 14, and a metal foil 15.

The transparent conducting substrate 11 has a transparent substrate 111 and a transparent conducting layer 112, which is disposed on the transparent substrate 111. The light can enter into the DSSC 1 through the transparent conducting substrate 11. The material of the transparent substrate 111 can include glass, or plastics, such as PET or other transparent polymers. The material of the transparent conducting layer 112 can be, for example, transparent conductive film or transparent conducting oxide (TCO), such as indium oxide tin (ITO), tin oxide, or zinc oxide. The material of the transparent conducting layer 112 also can be tin oxide doped with fluorine (SnO₂:F), and this kind of substrate is called an FTO substrate. The transparent conducting layer 112 can be a continuous conducting layer or include a plurality of unconnected conducting portions, and herein, it is illustrated as being a continuous transparent conducting layer without being patterned.

The dye layer 12 is disposed on the transparent conducting layer 112, and can be a continuous dye layer or include a plurality of unconnected dye portions. Herein, the dye layer 12 is illustrated to be a continuous dye layer without being patterned. For forming the dye layer 12, a dye-absorbing layer (such as titanium dioxide (TiO₂)) can be disposed on the transparent conducting layer 112, and then the dye is disposed so that the TiO₂ can absorb the dye to become the dye layer 12. The dye layer 12 will generate electrons by receiving the light, and the electrons will be transmitted to the transparent conducting layer 112 of the transparent conducting substrate 11. Herein, the dye in the dye layer 12 can include, for example, ruthenium metal complexes pigment, or organic pigment, such as methoxy pigment or phthalocyanine.

The electricity-collecting electrode 13 is disposed on the transparent conducting layer 112 and around the dye layer 12. The electricity-collecting electrode 13 has at least one frame portion 131, and herein has a single frame portion 131 for instance. The frame portion 131 is disposed around the dye layer 12. An edge of the frame portion 131 has a conducting connection portion 132, which functions as an electrode of the solar cell for transmitting the electricity outside. In this embodiment, the conducting connection portion 132 is a polygon, such as a rectangle, and disposed at a side of the frame portion 131, being a cathode for example.

The electricity-collecting electrode 13 is a silver paste for example. It also can be other kind of conducting paste, such as an aluminum paste or a copper paste. The electricity-collecting electrode 13 can be formed by printing, coating, sputtering, evaporation, or paste dispensing. The electricity-collecting electrode 13 can assist the electron transport of the dye layer 12. In detail, the electrons generated by the dye layer 12 will be transmitted to the transparent conducting layer 112 of the transparent conducting substrate 11, and then be transmitted to the electricity-collecting electrode 13 through the transparent conducting layer 112.

The insulating adhesive 14 is disposed around the dye layer 12 and on the electricity-collecting electrode 13, and even covers a part of the electricity-collecting electrode 13. The insulating adhesive 14 is disposed between the electricity-collecting electrode 13 and the metal foil 15 to electrically insulate them from each other. The insulating adhesive 14 can be a hot-melt adhesive, and have effects on connecting the electricity-collecting electrode 13 and preventing the electricity-collecting electrode 13 from being oxidized.

The metal foil 15 is disposed on the dye layer 12 and the insulating adhesive 14. The metal foil 15 can be a continuous metal foil or include a plurality of unconnected metal portions. Herein, the metal foil 15 is a continuous metal foil. Herein, the metal foil has a thickness between 30 μm and 100 μm for example. The metal foil 15 is disposed on the dye layer 12 and the insulating adhesive 14, but not covers the conducting connection portion 132 so that it doesn't electrically contact the conducting connection portion 132. The material of the metal foil 15 can include titanium (Ti), nickel, or stainless steel. The metal foil 15 is electrically connected with the dye layer 12, and can function as an anode of the solar cell for example. Besides, the metal foil 15 and the electricity-collecting electrode 13 can be included in an electrical loop.

The DSSC 1 further includes an electrolyte 16, which is disposed in the space formed by the metal foil 15, the insulating adhesive 14 and the dye layer 12. Because the highest point of the insulating adhesive 14 is higher than the dye layer 12, the space can be formed to contain the electrolyte 16. The metal foil 15 can be electrically connected with the dye layer 12 through the electrolyte 16, and function as another electrode of the solar cell.

The DSSC 1 can further include a package adhesive 17, which is disposed on the metal foil 15 and can prevent external objects from entering into the DSSC 1 so that the DSSC 1 can be prevented from being damaged. The package adhesive 17 also provides the DSSC 1 with the airtightness. The package adhesive 17 includes at least one first conducting hole 171 and at least one second conducting hole 172. The first conducting hole 171 is electrically connected with the electricity-collecting electrode 13, and the second conducting hole 172 is electrically connected with the metal foil 15. In detail, the first conducting hole 171 is electrically connected with the conducting connection portion 132 of the electricity-collecting electrode 13 by a wire. Otherwise, the conducting connection portion 132 can be preset with a proper height so that it can directly contact the first conducting hole 171 to achieve the electrical connection.

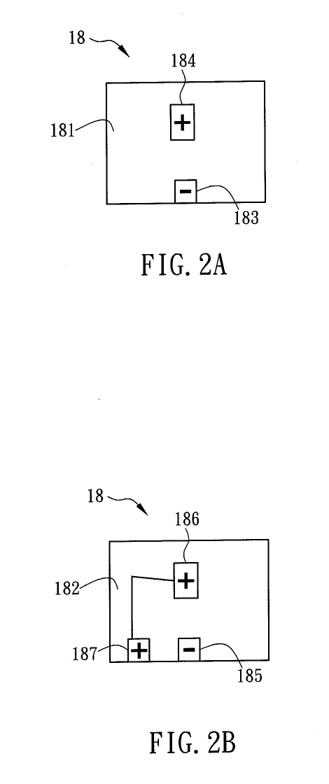

Referring to FIGS. 2A and 2B, for outputting the electricity generated by the photoelectric conversion, the DSSC 1 can further include a double-surface circuit board 18, which has a first surface 181 and a second surface 182 opposite to each other. FIG. 2A is a schematic diagram of the first surface 181, and FIG. 2B is a schematic diagram of the second surface 182. Referring to FIGS. 2A, 2B, and 1C, the first surface 181 has at least one first conducting pad 183 and at least one second conducting pad 184. The first conducting pad 183 is electrically connected with the first conducting hole 171, and the second conducting pad 184 is electrically connected with the second conducting hole 172. In the embodiment, the first conducting pad 183 is electrically connected with the first conducting hole 171 by the mutual contact, and the second conducting pad 184 is electrically connected with the second conducting hole 172 by the mutual contact, too. The second surface 182 of the double-surface circuit board 18 has a third conducting pad 185 and a fourth conducting pad 186. The double-surface circuit board 18 further has two holes (not shown), one of which is connected with the third conducting pad 185 and the first conducting pad 183, and the other is connected with the fourth conducting pad 186 and the second conducting pad 184. Accordingly, the electricity can be transmitted from the first and second conducting pads 183 and 184 located on the first surface 181 to the third and fourth conducting pads 185 and 186 located on the second surface 182. Besides, the double-surface circuit board 18 can further include a transferring pad 187. The transferring pad 187 is disposed on the second surface 182 and at an edge of the double-surface circuit board 18, and electrically connected with the fourth conducting pad 186. Thereby, the electricity can be transferred to the transferring pad 187 and the third conducting pad 185, both of which are disposed near the edge of the double-surface circuit board 18 so that the electricity can be easily transmitted to the outside. Accordingly, the DSSC 1 can be used like the present cell phone's rechargeable battery, having two adjacent pins located at the same side.

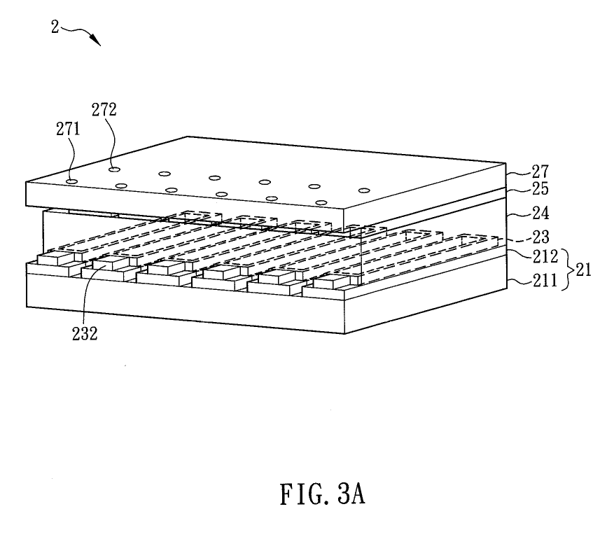

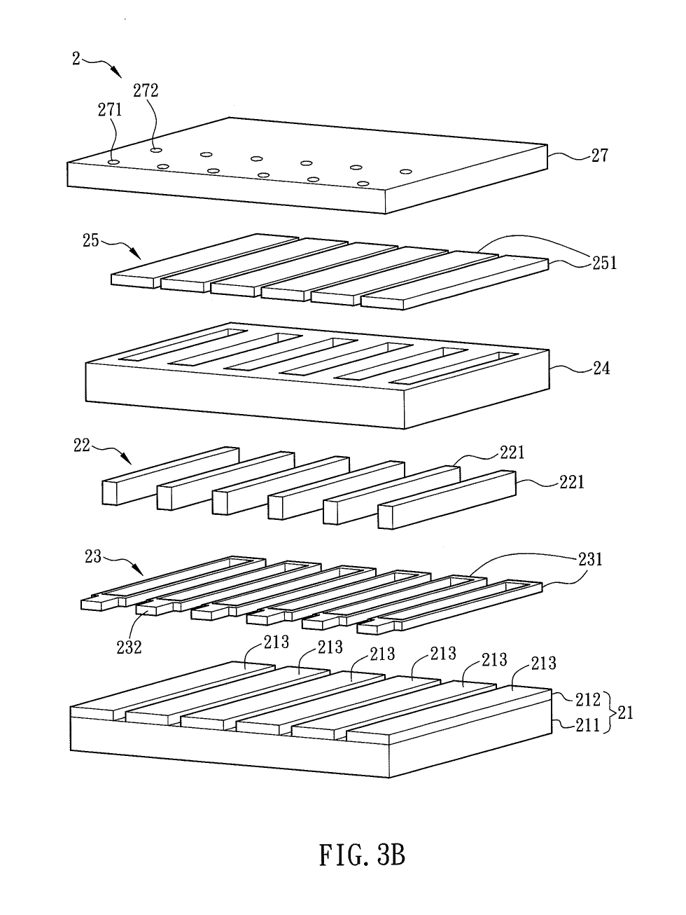

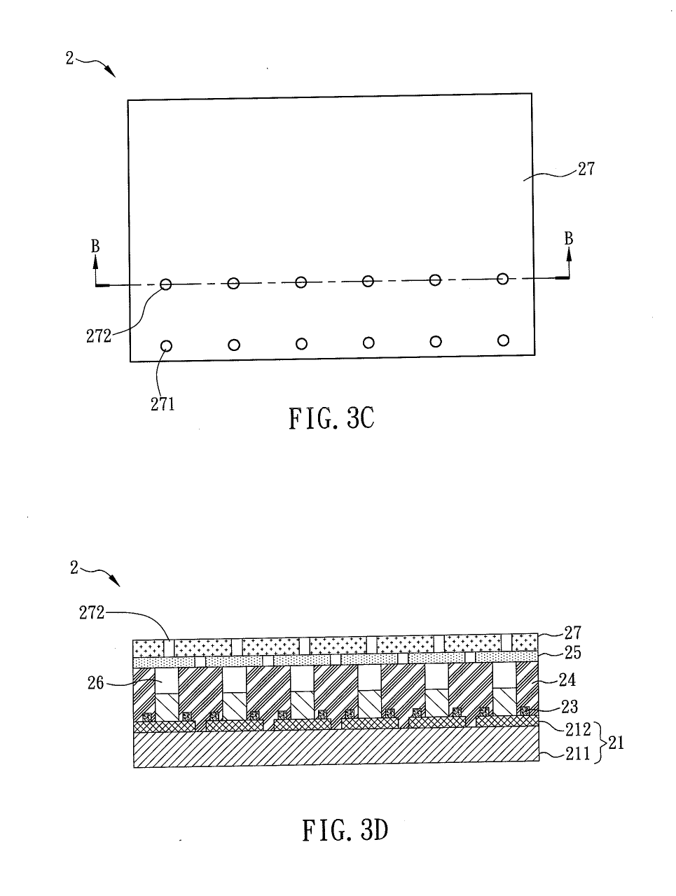

FIG. 3A is a schematic diagram of a dye sensitized solar cell (DSSC) 2 of a second embodiment of the invention, FIG. 3B is an exploded diagram of the DSSC 2, FIG. 3C is a top view of the DSSC 2, and FIG. 3D is a sectional diagram of the DSSC 2 taken along the line B-B in FIG. 3C. Referring to FIGS. 3A to 3D, the DSSC 2 includes a transparent conducting substrate 21, a dye layer 22, an electricity-collecting electrode 23, an insulating adhesive 24, a metal foil 25, an electrolyte 26, and a package adhesive 27. Since the above-mentioned elements' features are the same as the corresponding elements in the first embodiment, the detailed descriptions thereof are omitted here. However, the partial elements of the second embodiment have different structures from the first embodiment, and they will be illustrated as below.

In this embodiment, the transparent conducting layer 212 includes a plurality of unconnected transparent conducting portions 213. The transparent conducting layer 212 can be divided by laser cutting, mechanical cutting, chemical corrosion, or FTO printing. By dividing the transparent conducting layer 212, the DSSC 2 can be divided into several small batteries for the series or parallel connection and further for extending the application. Herein, the transparent conducting layer 212 has a plurality of separate and parallel rectangular conducting portions.

The dye layer 22 has a plurality of unconnected dye portions 221, which are disposed on the transparent conducting portions 212 respectively. The dye portion's shape is not limited, and it can be, for example, a rectangle or a regular polygon, such as a regular hexagon. Herein, matching the shape of the transparent conducting layer 212, the dye layer 22 is divided into a plurality of separate and parallel rectangles.

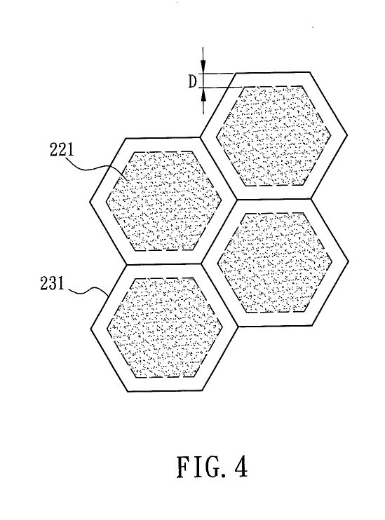

The electricity-colleting electrode 23 includes a plurality of frame portions 231, which are respectively disposed on the transparent conducting portions 212 and around the dye portions 221. The frame portion 231 is not limited in shape, which can be a rectangle or a regular polygon, such as a regular hexagon. When the frame portion 231 is a regular hexagon, the electricity-collecting electrode 23 can provide the optimum carrier transport efficiency. Accordingly, the electricity-collecting electrode 23 and the dye layer 22 therein are formed into a honeycomb, sharing mutual sides to become a close-packed structure, so that the dye area and the photoelectric converting efficiency can be enormously enhanced. Besides, the dye portion 221 of the dye layer 22 is also can be a regular hexagon, and disposed within the corresponding frame portion 231 of the electricity-collecting electrode 23. As shown in FIG. 4, the frame portion 231 of the electricity-collecting electrode 23 and the dye portion 221 of the dye layer 22 are each a regular hexagon. A distance D between the frame portion 231 and the dye portion 221 is between 0.1 mm and 5 mm, and preferably between 0.2 mm and 1 mm. According to such features, the power generating efficiency of the embodiment can be improved more effectively. Of course, the distance D can be changed according to the practical requirements. Besides, the line width of the frame portion 231 of the electricity-collecting electrode 23 is between 0.1 mm and 3 mm for example, and preferably between 0.2 mm and 1 mm.

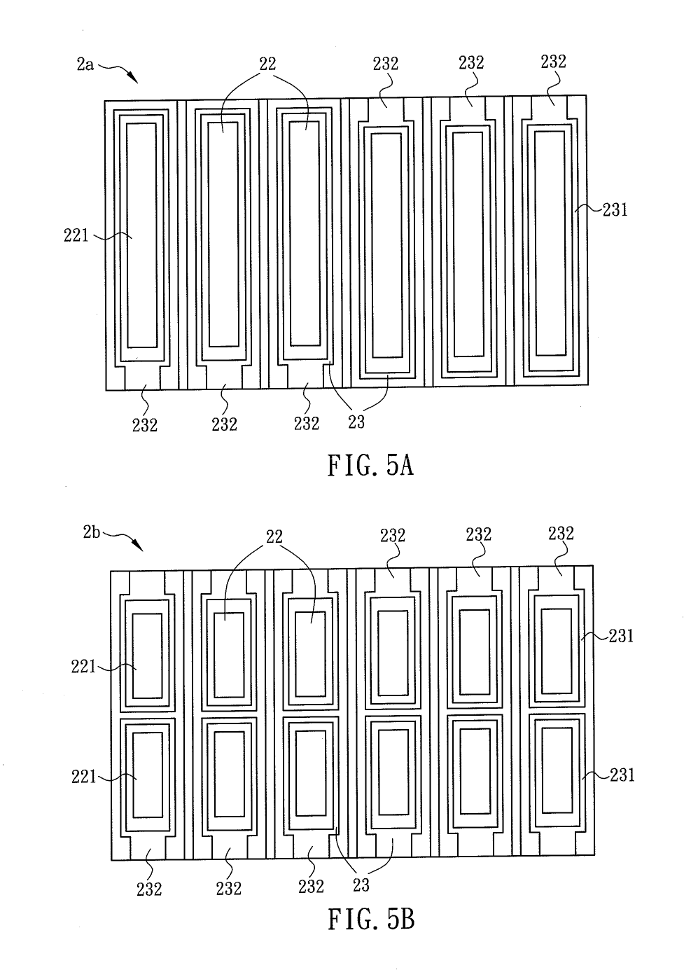

Referring to FIG. 3B, the electricity-collecting electrode 23 further includes at least one conducting connecting portion 232, which is connected with the frame portion 231. The conducting connection portions 232 can be disposed at a side or opposite sides of the transparent conducting substrate 21. Herein, the conducting connection portions 232 are illustrated as being disposed at a side of the transparent conducting substrate 21. Otherwise, the conducting connection portions 232 as shown in FIGS. 5A and 5B are disposed at the opposite sides of the transparent conducting substrate 21. FIG. 5A shows six dye portions 221 respectively corresponding to six frame portions 231 and six conducting connection portions 232, three of which are disposed at a side of the transparent conducting substrate 21, and the other three are disposed at the other side of the transparent conducting substrate 21. FIG. 5B shows twelve dye portions 221 respectively corresponding to twelve frame portions 231 and twelve conducting connection portions 232, six of which are disposed at a side of the transparent conducting substrate 21, and the other six are disposed at the other side of the transparent conducting substrate 21

Referring to FIGS. 3A to 3D, the metal foil 25 includes a plurality of unconnected metal portions 251, each of which is disposed corresponding to the corresponding dye portion 221 and transparent conducting portion 212, and has a size similar to the transparent conducting portion 212. The metal portions 251 don't cover the conducting connection portions 232 of the electricity-collecting electrode 23.

The package adhesive 27 has at least one first conducting hole 271 and at least one second conducting hole 272, and herein for example, it has six first conducting holes 271 and six second conducting holes 272. The first conducting holes 271 are electrically connected with the electricity-collecting electrode 23, and the second conducting holes 272 are electrically connected with the metal foil 25. In details, the first conducting holes 271 are electrically connected with the conducting connection portions 232 of the electricity-collecting electrode 23 respectively, by a wire for example, or by presetting the height of the conducting connection portion 232 so that the conducting connection portion 232 can directly contact the first conducting hole 271. In details, the second conducting holes 272 are electrically connected with the metal portions 251 of the metal foil 25 respectively.

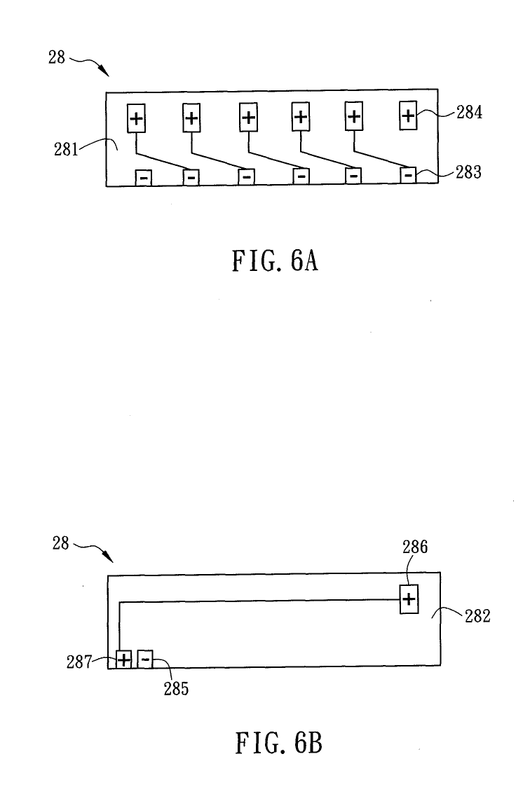

Referring to FIGS. 6A and 6B, for transmitting the electricity generated by the photoelectric conversion outside, the DSSC 2 can further include a double-surface circuit board 28, which has a first surface 281 and a second surface 282 opposite to each other. FIG. 6A is a schematic diagram of the first surface 281, and FIG. 6B is a schematic diagram of the second surface 282. The first surface 281 has at least one first conducting pad 283 and at least one second conducting pad 284, and herein for example, it has six first conducting pads 283 and six second conducting pads 284. Referring to FIGS. 6A, 6B, and 3C, the first conducting pads 283 are electrically connected with the first conducting holes 271 respectively, and the second conducting pads 284 are electrically connected with the second conducting holes 272 respectively. In the embodiment, the first conducting pads 283 are electrically connected with the first conducting holes 271 by the mutual contact, and the second conducting pads 284 are electrically connected with the second conducting holes 272 by the mutual contact, too. Five of the first conducting pads 283 are electrically connected with five of the second conducting pads 284 respectively for the series connection.

The second surface 282 of the double-surface circuit board 28 has a third conducting pad 285 and a fourth conducting pad 286. The double-surface circuit board 28 further has two holes (not shown), one of which is connected with the third conducting pad 285 and one of the first conducting pads 283 (the leftest first conducting pad 283 in the figure for example), and the other is connected with the fourth conducting pad 286 and one of the second conducting pads 284 (the most right second conducting pad 284 in the figure for example). Accordingly, the electricity can be transmitted to the third and fourth conducting pads 285 and 286. Besides, the double-surface circuit board 28 can further include a transferring pad 287. The transferring pad 187 is disposed on the second surface 282 and at an edge of the double-surface circuit board 28, and electrically connected with the fourth conducting pad 286. Thereby, the electricity can be transferred to the transferring pad 287 and the third conducting pad 285, both of which are disposed near the edge of the double-surface circuit board 28, through the circuit of the double-surface circuit board 28. Therefore, the electricity can be easily drawn out so as to extend the application of the product. For example, the DSSC 2 can be used like the present cell phone's rechargeable battery, having two adjacent pins located at the same side.

In summary, the DSSC of the invention only has a substrate, on which the dye layer, the electricity-collecting electrode, the insulating adhesive, and the metal foil are disposed. Besides, the metal foil and the electricity-collecting electrode can be included in an electrical loop, and the metal foil can function as a catalytic layer. Further, the insulating adhesive insulates the metal foil and the electricity-collecting electrode (with the dye layer) from each other so that the DSSC can function normally to conduct a photoelectric conversion. Accordingly, the DSSC of the invention has a new structure to advantage the product's compactness as well as competitiveness.

Furthermore, there are some advantages as the electricity-collecting electrode and the dye layer are formed into hexagon, such as:

1. Less Material Waste and Higher Package Density

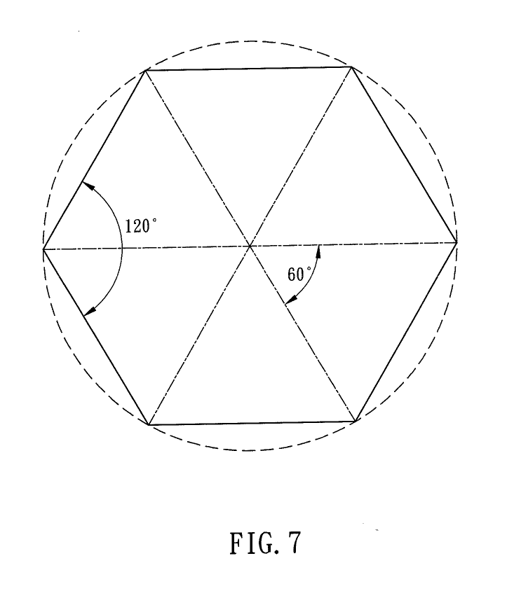

FIG. 7 is a schematic diagram of an equilateral hexagon inscribed in a circle. When an equilateral hexagon is inscribed in a circle, the circle's radius just equals a side of the equilateral hexagon, and the equilateral hexagon's longest diagonal equals the diameter of the circle. Accordingly, the equilateral hexagon can be regarded as an approximate figure of the circle. Among polygons with the same perimeter, an equilateral polygon has the largest area, and the equilateral polygon with more sides has larger area. The area of the circle is larger than any equilateral polygon with the same perimeter as the circle. However, in point of the package, circles can not share sides with each other, but only points are connected when circles are packed together, so the circle's package density is poor and may leave more unused space. By contrast, the equilateral hexagon can make less material waste and a higher package density.

2. Average Stress

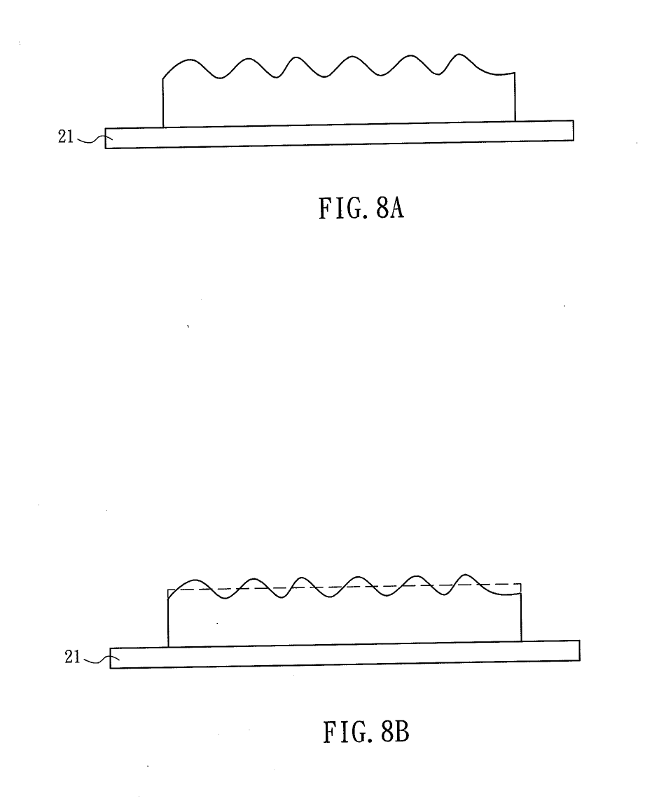

The equilateral hexagon structure is common in chemistry. Subjected to the resonance effect, the structure of a benzene ring is an equilateral hexagon. Graphite has a successive layer structure in which carbon molecules are arranged in equilateral hexagons, and ice crystal is also a hexagon. Besides, when water molecules freeze, they will be attracted by the hydrogen bonds and then become equilateral hexagons in structure, just because the equilateral hexagon is subjected to the average stress. FIGS. 8A and 8B are schematic diagrams showing titanium dioxide as the dye-absorbing layer disposed on the transparent conducting substrate 21. When the transparent conducting substrate 21 is coated with the titanium dioxide, the titanium dioxide's surface is rough. The titanium dioxide layer needs to be spread out so as to be leveled. When the titanium dioxide layer is spread out by the gravity, the thickness difference of the titanium dioxide layer will be reduced a lot because of the average stress of the hexagon that has a geometrically approximate to a circle, therefore decreasing the variance and enhancing the yield.

3. Enhanced Electron Transport Efficiency

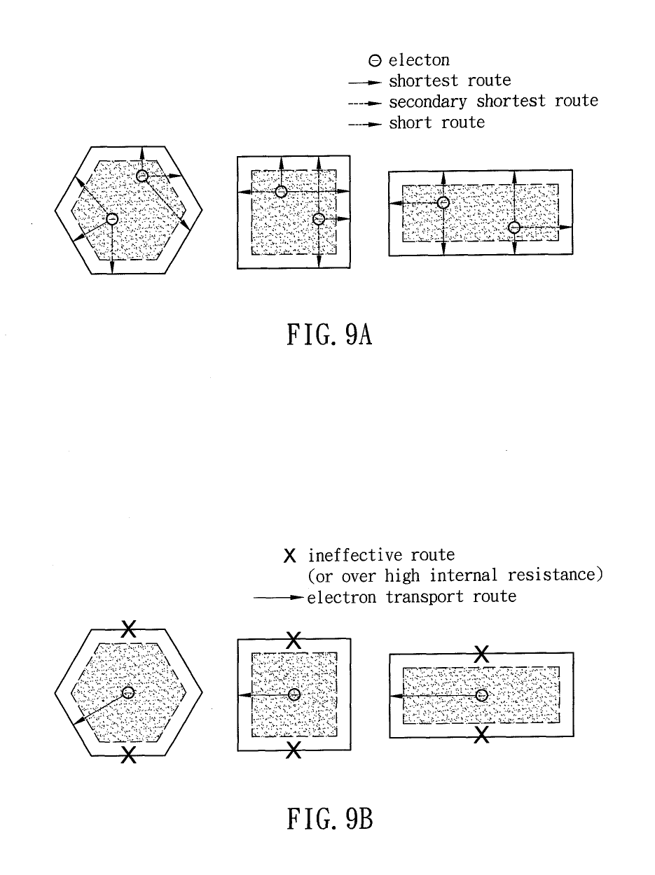

FIG. 9A is a schematic diagram showing the dye portions in the three different forms (hexagon, square, rectangle) and the electron transport routes of the electricity-collecting electrode. The electron transport routes can include a shortest route, a secondary shortest route, and a short route. However, actually in the electron's transport, the shortest route will be ineffective due to the over high internal resistance, as shown in FIG. 9B. If the shortest route is ineffective, the travelling distance of the electron will be elongated, thus increasing the internal resistance. However, the regular hexagon has equal distances from its center to each side, so the travelling distance will not be increased when the route therein is ineffective.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A dye sensitized solar cell, comprising:
a transparent conducting substrate having a transparent substrate and a transparent conducting layer that is disposed on the transparent substrate;
a dye layer disposed on the transparent conducting layer;
an electricity-collecting electrode disposed on the transparent conducting layer and around the dye layer;
an insulating adhesive disposed around the dye layer and on the electricity-collecting electrode; and
a metal foil disposed on the dye layer and the insulating adhesive.

2. The dye sensitized solar cell as recited in claim 1, wherein the transparent conducting layer is a continuous transparent conducting layer or includes a plurality of unconnected transparent conducting portions.

3. The dye sensitized solar cell as recited in claim 1, wherein the transparent conducting layer includes a plurality of unconnected transparent conducting portions, and the dye layer includes a plurality of unconnected dye portions that are respectively disposed on the transparent conducting portions.

4. The dye sensitized solar cell as recited in claim 1, wherein the dye layer includes a plurality of unconnected dye portions that each are a regular polygon or a rectangle.

5. The dye sensitized solar cell as recited in claim 1, wherein the electricity-collecting electrode includes at least one frame portion.

6. The dye sensitized solar cell as recited in claim 5, wherein the electricity-collecting electrode further includes a conducting connection portion that is connected with the frame portion.

7. The dye sensitized solar cell as recited in claim 6, wherein the conducting connection portions are disposed at a side or opposite sides of the transparent conducting substrate.

8. The dye sensitized solar cell as recited in claim 1, wherein the metal foil is a continuous metal foil or includes a plurality of unconnected metal portions.

9. The dye sensitized solar cell as recited in claim 1, wherein the material of the metal foil includes titanium, nickel, or stainless steel.

10. The dye sensitized solar cell as recited in claim 1, further comprising:
a package adhesive disposed on the metal foil.

11. The dye sensitized solar cell as recited in claim 10, wherein the package adhesive includes at least one first conducting hole and at least one second conducting hole.

12. The dye sensitized solar cell as recited in claim 11, wherein the first conducting hole is electrically connected with the electricity-collecting electrode, and the second conducting hole is electrically connected with the metal foil.

13. The dye sensitized solar cell as recited in claim 12, further comprising:
a double-surface circuit board having a first surface and a second surface opposite to the first surface, wherein the first surface has at least one first conducting pad and at least one second conducting pad, the first conducting pad is electrically connected with the first conducting hole, and the second conducting pad is electrically connected with the second conducting hole.

14. The dye sensitized solar cell as recited in claim 13, wherein the double-surface circuit board further has two holes, the second surface of the double-surface circuit board has a third conducting pad and a fourth conducting pad, one of the holes is connected with the third conducting pad and one of the first conducting pads, and the other hole is connected with the fourth conducting pad and one of the second conducting pads.

15. The dye sensitized solar cell as recited in claim 14, wherein the double-surface circuit board further has a transferring pad that is disposed on the second surface and at an edge of the double-surface circuit board and electrically connected with the fourth conducting pad.
